(19) United States
(12) Patent Application Publication
(10) Pub. No.: US 2019/0103394 A1
(43) Pub. Date: Apr. 4, 2019

(54) THERMALLY CONSCIOUS STANDARD CELLS

(71) Applicant: QUALCOMM Incorporated, San Diego, CA (US)

(72) Inventors: Sean Charles Andrews, Solana Beach, CA (US); Yong Ju Lee, San Diego, CA (US)

(21) Appl. No.: 15/719,877

(22) Filed: Sep. 29, 2017

(51) Int. Cl. H01L 27/02; H01L 23/373; H01L 23/532

(52) U.S. Cl. CPC H01L 27/0211; H01L 23/373; H01L 23/3732; H01L 23/3737; H01L 23/5329

(57) ABSTRACT

In certain aspects, an integrated circuit comprises a first standard cell having a height equal to a cell height, wherein the first standard cell comprises a first dielectric material in a first layer. The integrated circuit comprises a second standard cell having a height equal to the cell height and aligning with the first standard cell, wherein the second standard cell comprises the first dielectric material in the first layer. The integrated circuit further comprises a first thermal cell having a height equal to the cell height and aligning with and abutting to both the first standard cell and the second standard cell; and wherein the first thermal cell comprises a second dielectric material in the first layer having a higher thermal conductivity than that of the first dielectric material.

### BACKGROUND

### Field

Aspects of the present disclosure relate generally to thermal management in digital circuit design, and more particularly, to thermally conscious circuit design using standard cells.

### Background

Power is required to operate integrated circuits (ICs). This power is provided to the IC in the form of voltage and current through power supply pins. The consumption of power creates heat and results in a junction temperature different from the surrounding ambient temperature. Two main thermal sources exist at the chip level: transistor junctions and resistive layers. The lifetime of the device and the speed of the circuit are mainly driven by the junction temperature of the transistors and must be maintained as low as possible.

Conventional thermal management generally relies on packaging technology, such as using a heat sink attached to an integrated circuit die. However, problems still exist with channeling the heat from the heat source, the transistors and high resistive and high density local interconnects, to the heat sink. With increasing level of integration, faster clock frequency, higher heat density in the circuit, and the introduction of new material (often with poor thermal properties), it is challenging to have an effective thermal management system with packaging level solution only.

Accordingly, it would be beneficial to provide an improved heat dissipation system and method inside an integrated circuit die.

### SUMMARY

The following presents a simplified summary of one or more implementations to provide a basic understanding of such implementations. This summary is not an extensive overview of all contemplated implementations, and is intended to neither identify key nor critical elements of all implementations nor delineate the scope of any or all implementations. The sole purpose of the summary is to present concepts relate to one or more implementations in a simplified form as a prelude to a more detailed description that is presented later.

In one aspect, an integrated circuit comprises a first standard cell having a height equal to a cell height, wherein the first standard cell comprises a first dielectric material in a first layer. The integrated circuit comprises a second standard cell having a height equal to the cell height and aligning with the first standard cell, wherein the second standard cell comprises the first dielectric material in the first layer. The integrated circuit further comprises a first thermal cell having a height equal to the cell height and aligning with and abutting to both the first standard cell and the second standard cell; and wherein the first thermal cell comprises a second dielectric material in the first layer having a higher thermal conductivity than that of the first dielectric material.

In another aspect, a method comprises placing a first standard cell in a circuit row, wherein the first standard cell has a height equal to a cell height and comprises a first dielectric material in a first layer. The method also comprises placing a second standard cell in the circuit row, wherein the second standard cell has a height equal to the cell height and comprises the first dielectric material in the first layer. The method further comprises placing a first thermal cell in the circuit row abutting to both the first standard cell and the second standard cell, wherein the first thermal cell has a height equal to the cell height; wherein the first standard cell, the second standard cell, and the first thermal cell are aligned; and wherein the first thermal cell comprises a second dielectric material in the first layer having a higher thermal conductivity than that of the first dielectric material.

To accomplish the foregoing and related ends, one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 illustrates an exemplary circuit placement using standard cells according to certain aspects of the present disclosure.

FIG. 2 illustrates an exemplary design with thermal cells according to certain aspects of the present disclosure.

FIG. 3 illustrates an exemplary cross-section of the FIG. 2 along line A-A′ according to certain aspects of the present disclosure.

FIG. 4 illustrates an exemplary cross-section of the FIG. 2 along line B-B′ according to certain aspects of the present disclosure.

FIG. 5 illustrates another exemplary cross-section of the FIG. 2 along line B-B′ according to certain aspects of the present disclosure

FIG. 6 illustrates an exemplary method of placing a thermal cell in a circuit design according to certain aspects of the present disclosure.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing an understanding of the various concepts. However, it will be apparent to those skilled in the art that these concepts may be practiced without these specific details. In some instances, well-known structures and components are shown in block diagram form in order to avoid obscuring such concepts.

In semiconductor design, standard cell methodology is a method of designing application-specific integrated circuits (ASICs) that contains mostly digital logics. A standard cell is a group of transistor and interconnect structures that provides a Boolean logic function (e.g., AND, OR, XOR, XNOR, inverters) or a storage function (e.g., flipflop or latch). A standard cell library is a collection of standard cells, which typically perform low-level electronic logic functions such as AND, OR, INVERT, flip-flops, latches, and buffers. These standard cells are realized as fixed-height, variable-width, full-custom cells. The key aspect with these standard cells is that they are of a fixed height, which enables them to be placed in rows, easing the process of automated digital layout. In a design with standard cells, the standard cells are placed on the row. To make sure that each cell gets power and ground connection, the cells are abutted together so that the VDD and VSS terminals of neighboring standard cells short together. This makes it possible to tap power only at one point anywhere in the row. But it is virtually impossible to fill 100% of the die area with regular standard cells. So, integrated circuit designers typically use filler cells to fill these spaces between regular standard library cells to maintain the continuity of Nwell or power (e.g., VDD) and ground (e.g., VSS) rails.

In addition to the filler cells, other cells are available in a standard cell library that a circuit designer may use. For example, decap cells are added in the design between power and ground rails to counter the functional failure due to dynamic IR drop; tie-high and tie-low cells are used to connect the gate of a transistor to either a power or a ground; and tap cells are traditionally used to connect the power or ground to the substrate or Nwell, respectively. To ameliorate thermal issues, according to certain aspects of present disclosure, thermal cells may be added to the standard cell library. The thermal cells may replace the filler cells in a circuit design and/or be strategically placed in a location where neighboring cells may experience thermal issues. For ease of explanation, filler cells, decap cells, tie-high cells, tie-low cells, and/or thermal cells may be referred to as “special cells” in the following description.

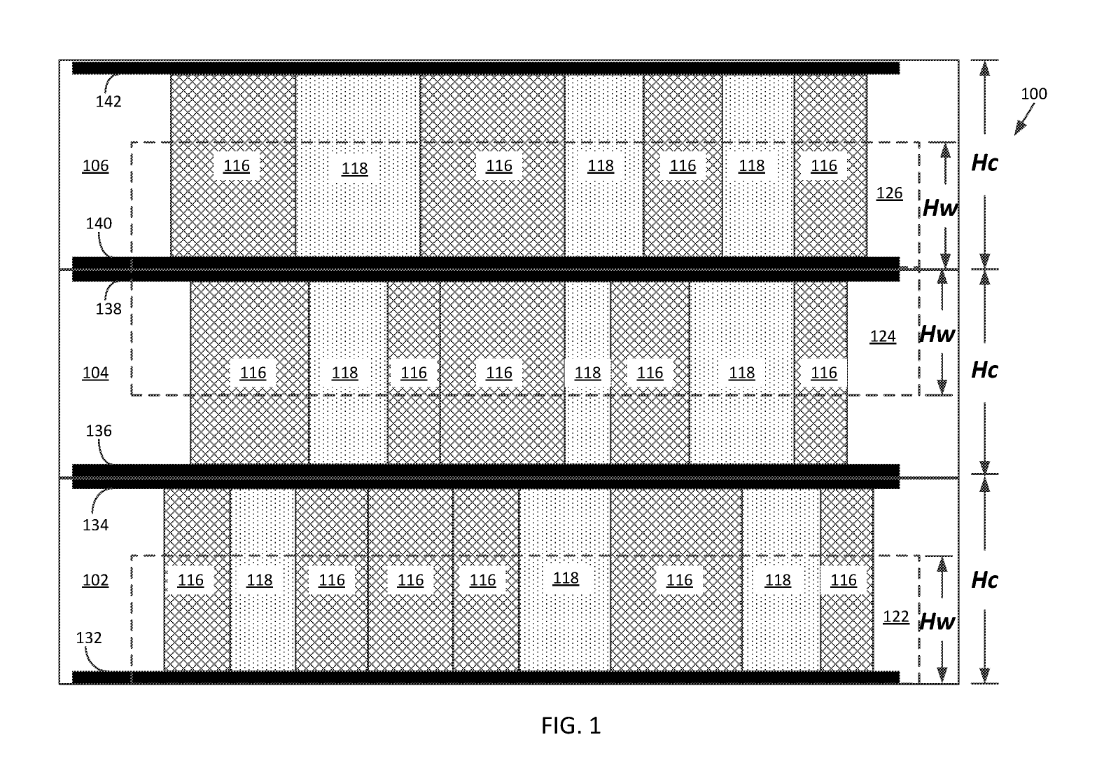

FIG. 1 illustrates an exemplary circuit layout using standard cells. The circuit 100 includes a plurality of circuit rows 102, 104, 106. Each of the circuit rows 102, 104, 106 comprises a plurality of standard cells 116 and a plurality of special cells 118. Each of the plurality of standard cells 116 or each of the plurality of special cells 118 comprises a power (e.g., VDD) rail and a ground (e.g., VSS) rail. Within the same circuit row, the power rails of the plurality of standard cells 116 and the plurality of special cells 118 are physically abutted and electrically coupled along a straight line to form a common power rail. Similarly, within the same circuit row, the ground rails of the plurality of standard cells 116 and the plurality of special cells 118 are physically abutted and electrically coupled along a straight line to form a common ground rail. For example, the circuit row 102 comprises a straight line common power rail 132 and a straight line common ground rail 134 formed by the respective power rails and ground rails of the plurality of standard cells 116 and the plurality of special cells 118 in the circuit row 102. Similarly, the circuit row 104 comprises a straight line common power rail 138 and a straight line common ground rail 136 formed by the respective power rails and ground rails of the plurality of standard cells 116 and the plurality of special cells 118 in the circuit row 104. Likewise, the circuit row 106 comprises a straight line common power rail 140 and a straight line common ground rail 142 formed by the respective power rails and ground rails of the plurality of standard cells 116 and the plurality of special cells 118 in the circuit row 106.

Although the straight line common power rails and the straight line common ground rails illustrated in FIG. 1 are at the top or bottom of the circuit rows, other alternatives are possible. For example, a straight line common power rail may be offset from the top or bottom of the circuit row by a predefined amount. Likewise, a straight line common ground rail may be offset from the top or bottom of the circuit row by the same or another predefined amount.

A typical standard cell comprises an Nwell where one or more PMOS transistors form.

In a circuit designed with standard cells, the Nwell for each cell are abutted and formed a large single common Nwell. For example, the circuit row 102 comprises a single Nwell 122 formed by the Nwells for the plurality of standard cells 116 and the plurality of special cells 118 in the circuit row 102. The circuit row 104 comprises a single Nwell 124 formed by the Nwells for the plurality of standard cells 116 and the plurality of special cells 118 in the circuit row 104. Finally, the circuit row 106 comprises a single common Nwell 126 formed by the Nwells for the plurality of standard cells 116 and the plurality of special cells 118 in the circuit row 106. Each Nwell for each of the plurality of standard cells 116 or each of the plurality of special cells 118 has a same height, Hw. The width of the Nwells for each of the plurality of standard cells 116 or each of the plurality of special cells 118, however, may be different. In addition, although FIG. 1 illustrates same Nwell heights for all three circuit rows 102, 104, 106, the Nwell height of one circuit row may be the same as or different to the height of another circuit row.

When placing two circuit rows next to each other, it is common to flip one of the circuit rows so that either the common power rail or the common ground rail are abutted and coupled (e.g., the corresponding power rails touch and electrically connected). Such arrangement also enables the Nwells in the two circuit rows to be abutted and merged as one large Nwell. For example, the circuit row 102 and the circuit row 104 are arranged in such a way that their respective common ground rails 134 and 136 are abutted and merged as one wider common ground rails along a straight line. The circuit row 104 and the circuit row 106 are arranged in such a way that their respective common power rails 138 and 140 are abutted and merged and their respective common Nwells 124 and 126 are abutted and merged.

All the standard cells 116 and the special cells 118 in each circuit row 102, 104, 106 have a same row height, Hc. The standard cells 116 and the special cells 118 are usually designed with the same height but may show slightly height difference caused by process variation. Such difference is usually insignificant. The widths of the standard cells 116 or the widths of the special cells 118 may be different. In addition, although FIG. 1 illustrates a same row height for all three circuit rows 102, 104, 106, the row height of any one circuit row may differ to the row height of other circuit rows.

With continuing scaling of the process technology, more active devices with higher drive capability are packed into ever decreasing area, resulting in more power density in a local area. This translates to a higher local self-heat, or temperature increase, in the local area due to local power consumption, leading to local hotspots. Conventional approach relies on electrical conducting materials, such interconnects, which are usually also good thermal conducting materials, to spread the heat away from the local hotspots. However, most material in the local area are dielectric material, which generally has a poor thermal conductivity. One or more thermal cells, with good thermal conductivity, may be added to the standard cell library. Some of the special cells 118 as illustrated in FIG. 1 may be the thermal cells. The thermal cells may replace other special cells in the circuit rows and/or be strategically inserted in places next to the standard cells 116 to help spread and channel the heat from a local hotspot.

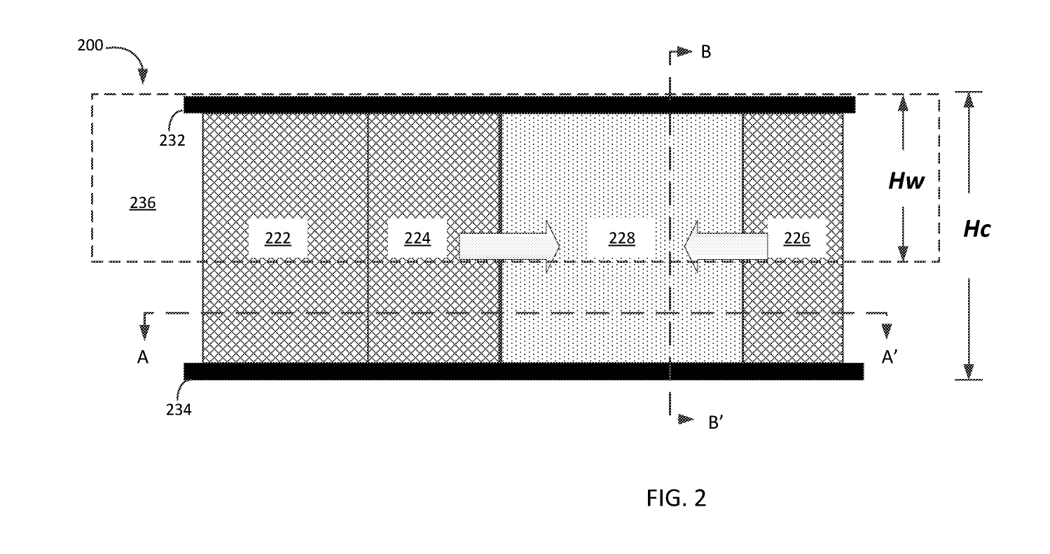

FIG. 2 illustrates an exemplary design with thermal cells. An integrated circuit 200 comprises a plurality of standard cells 222, 224, 226, each having a same height, Hc. The integrated circuit 200 further comprises a thermal cell 228 abutting the standard cell 224 to the left and the standard cell 226 to the right. The thermal cell 228 has a height that is same as the plurality of the standard cells 222, 224, 226. The integrated circuit 200 also comprises a common Nwell formed by merging individual Nwells for the plurality of standard cells 222, 224, 226 and the thermal cell 228. Each Nwell for the plurality of standard cells 222, 224, 226 and the thermal cell 228 has a same height, Hw. A straight line common power rail 232 and a straight line common ground rail 234 are formed by abutting the individual power rails and ground rails of the plurality of standard cells 222, 224, 226 and the thermal cell 228, respectively. Although the straight line common power rail and the straight line common ground rail illustrated are at the top or bottom of the cells, other alternatives are possible. For example, a straight line common power rail may be offset from the top or bottom by a predefined amount. Likewise, a straight line common ground rail may be offset from the top or bottom by the same or another predefined amount.

The thermal cells may be placed next to a local hotspot. For example, if the standard cell 224 generates a large amount of heat during operation, the thermal cell 228 may be placed next to the standard cell 224, as illustrated in FIG. 2. Alternatively, if it is necessary to place one or more other regular standard cells immediately next to the standard cell with hotspot due to performance requirement or other design restriction, then the thermal cell 228 may be placed one or more standard cells away. For example, if the standard cell 222 is a hotspot, but it is necessary to place the standard cell 224 right next to the standard cell 222, then the thermal cell 228 may be placed next to the standard cell 224, not right next to the standard cell 222.

Unlike dielectric materials in standard cells, such as SiO₂ or Si₃N₄, which usually have poor thermal conductivity, the thermal cell 228 comprises materials with high thermal conductivity that, like the dielectric materials in the standard cells 222, 224, 226, is electrically insulating. There are a variety of materials that may be used to serve this purpose. For example, aluminum nitride (AlN) has good dielectric property, high thermal conductivity, and low thermal expansion coefficient (close to that of silicon) and could be a good dielectric material for the thermal cell 228. AlN may be deposited with a sputtering process or other suitable technologies. Boron nitride (BN) is another material may be used for a thermal cell. BN is a very good electrical insulator. It offers very high thermal conductivity. BN may be deposited through chemical vapor deposition (CVD) or other suitable technologies. Polycrystalline diamond is a synthetic diamond through CVD process by which diamond may be grown from a hydrocarbon gas mixture. Pure synthetic diamond has high thermal conductivity with negligible electrical conductivity. Other suitable materials including AlN alloys, BN alloys, and polycrystalline diamond alloy.

The use of thermal cells helps remove and spread heat from the neighboring hotspots. The heat from the hotspot standard cells may be spread to the thermal cells and further channeled through the substrate to the air. For example, the heat generated by the standard cell 224 does not only spread out to the air through the substrate right below the standard cell 224, but also through the neighboring thermal cell 228, which has a higher thermal conductivity. From the thermal cell 228, the heat may be further spread out to the air through the substrate right below the thermal cell 228. Thus, the heat is dissipated more rapidly and efficiently.

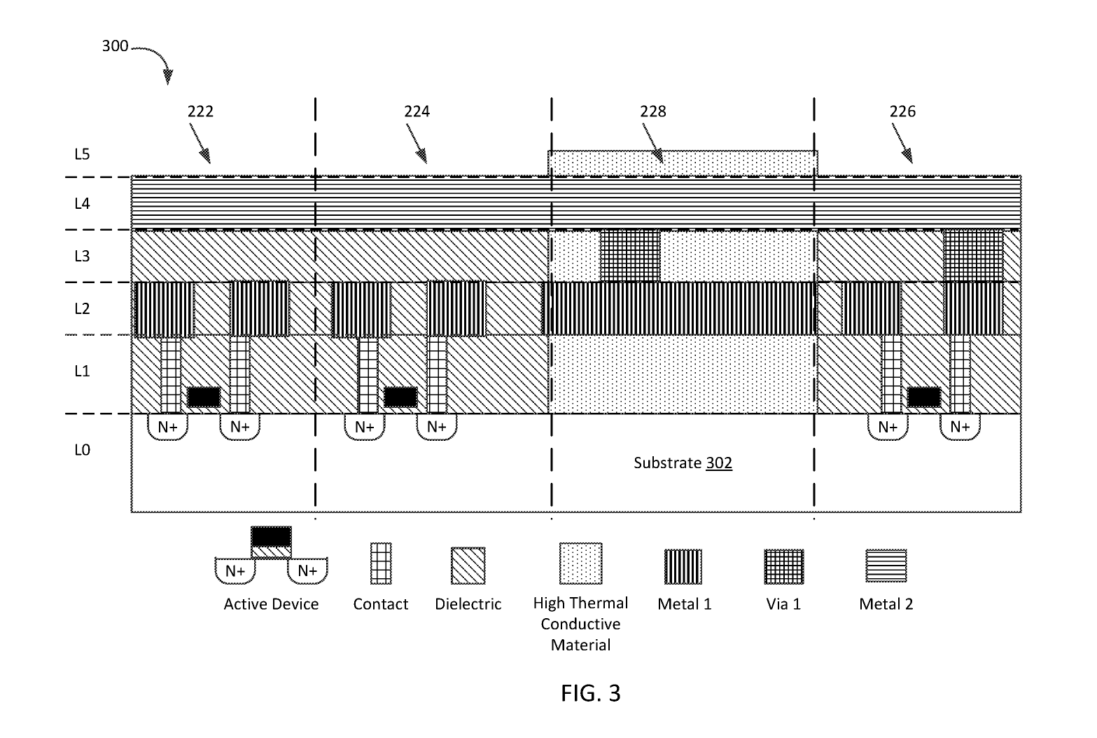

FIG. 3 illustrates an exemplary cross-section of the FIG. 2 along line A-A′. The drawing is for illustration purpose and is not intended to show every detail of an actual integrated circuit die. The cross-section 300 shows the standard cells 222, 224, 226 and the thermal cell 228. The cross-section 300 only shows up to Metal 2 (as described herein below). An integrated circuit die may have one or more stacked layers beyond Metal 2. From bottom to top, the cross-section 300 is roughly divided into a plurality of levels or layers: L0, L1, L2, L3, L4, L5, and so on. Layer L0 is the integrated circuit substrate. Active devices, such as NMOS or PMOS transistors, are built in and on top of the substrate. For example, Nwell for PMOS transistors, source or drain diffusion, body contact, etc., are in this layer. Layer L1 is a contact layer. It may comprise contacts to the source, drain, or gate of a transistor. It may also comprise the gates of the transistors. Layer L2 is Metal 1 layer. Layer L3 is Via 1 layer. Layer L4 is Metal 2 layer. Layer L5 is a catchall layer, for anything beyond Metal 2. The layering illustrated in FIG. 3 is for illustration purpose only. Alternative layering is possible.

Each of the plurality of layers L0-L5 also comprises dielectric materials. The dielectric material for each layer may be the same or different. The dielectric materials for different standard cells are usually the same at the same levels or layers. However, the dielectric material for a thermal cell may be different to the dielectric material for the standard cell at the same level or layer. The dielectric material for a thermal cell has a higher thermal conductivity than the one in the standard cell. For example, the dielectric material in layer L1 may be SiO₂ in the standard cells 222, 224, 226 while the dielectric material in layer L1 may be AlN, BN, or polycrystalline diamond in the thermal cell 228.

Although the cross-section 300 is divided into multiple layers for illustration purpose, in an actual integrated circuit die, each layer of the plurality of layers L0-L5 may comprise multiple sub-layers due to different materials and/or manufacturing steps used. For example, the gate of a transistor in layer L1 may comprise a stack of multiple materials made in multiple steps. A dielectric layer in each layer of the plurality of layers L0-L5 for a standard cell may comprise an etch stop layer at the bottom. A metal layer may comprise an adhesion layer and/or a barrier layer. On the other hand, some materials may cross over multiple layers or sub-layers of the plurality of layers L0-L5. For example, in a dual damascene copper process, dielectric materials for layers L3 and L4 may be made with one deposition process, so may be the Via 1 and Metal 2 layer.

The thermal materials in the thermal cell 228 may be deposited layer by layer from L1 to L5. Alternatively, the thermal materials in the thermal cell 228 may be deposited in multiple steps in multiple sub-layers in some of the plurality of layers L1-L5. Alternatively, the thermal materials in the thermal cell 228 may be deposited in one step for all the layers. Alternatively, the thermal materials in the thermal cell 228 may be deposited in the same one step (or same multiple steps) for multiple layers, such as layers L1 and L2, and in another step (or multiple steps) for other layers, such as layers L3 and L4. In addition, the thermal materials in one layer or one sub-layer may be different to the thermal materials in another layer or another sub-layer. For example, one layer or one sub-layer may comprise AlN while another one may comprise BN. Alternatively, some layers or sub-layers of the thermal cell 228 may comprise same dielectric materials as the standard cells 222, 224, 226.

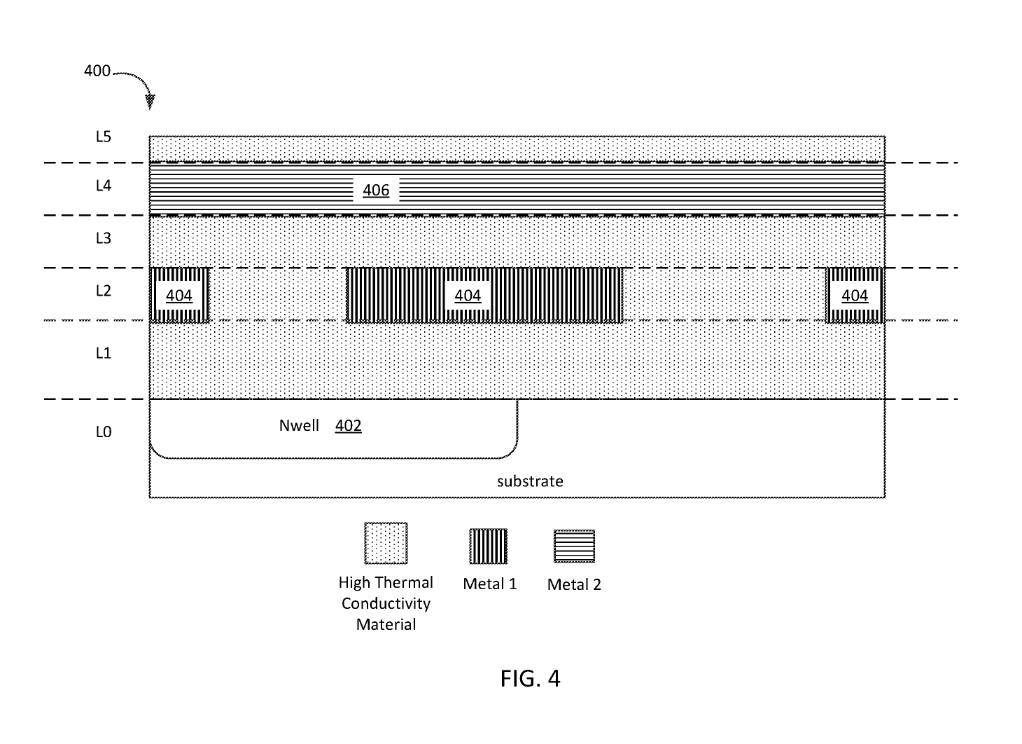

FIG. 4 illustrates an exemplary cross-section of the FIG. 2 along line B-B′. The cross-section 400 is along the thermal cell 228 only. For ease of explanation, like the cross-section 300, the cross-section 400 is for illustration purpose and is not intended to show every detail of an actual integrated circuit die. From bottom to top, the cross-section 400 is also roughly divided into a plurality of levels or layers: L0, L1, L2, L3, L4, L5, and so on. Layer L0 is the integrated circuit substrate. Although no active devices locate in the thermal cell 228, there may be an Nwell 402 in the substrate to maintain the Nwell continuity when the thermal cell 228 is placed abutted to other standard cells, such as the standard cells 224, 226. Similarly, there may be optional Metal 1 404 or Metal 2 406 lines for the power rail and the ground rail continuity when the thermal cell 228 is placed abutted to other standard cells, such as the standard cells 224, 226.

The majority of the thermal cell 228 is filled with high thermal conductivity materials, such as AlN, BN, polycrystalline diamond, their alloys, other suitable materials, or their combinations. The thermal materials may be filled by deposition process, such as CVD, or other suitable technologies. The thermal materials may be placed layer by layer (or sub-layer by sub-layer) or multiple layers in the same one step (or the same multiple steps). Alternatively, one layer (or sub-layer) may comprise one type of thermal material while another layer (or sub-layer) may comprise another type of thermal material. The high conductivity thermal materials provide an additional path for heat generated by the neighboring standard cells (e.g., the standard cells 222, 224, 226) to spread out to the air.

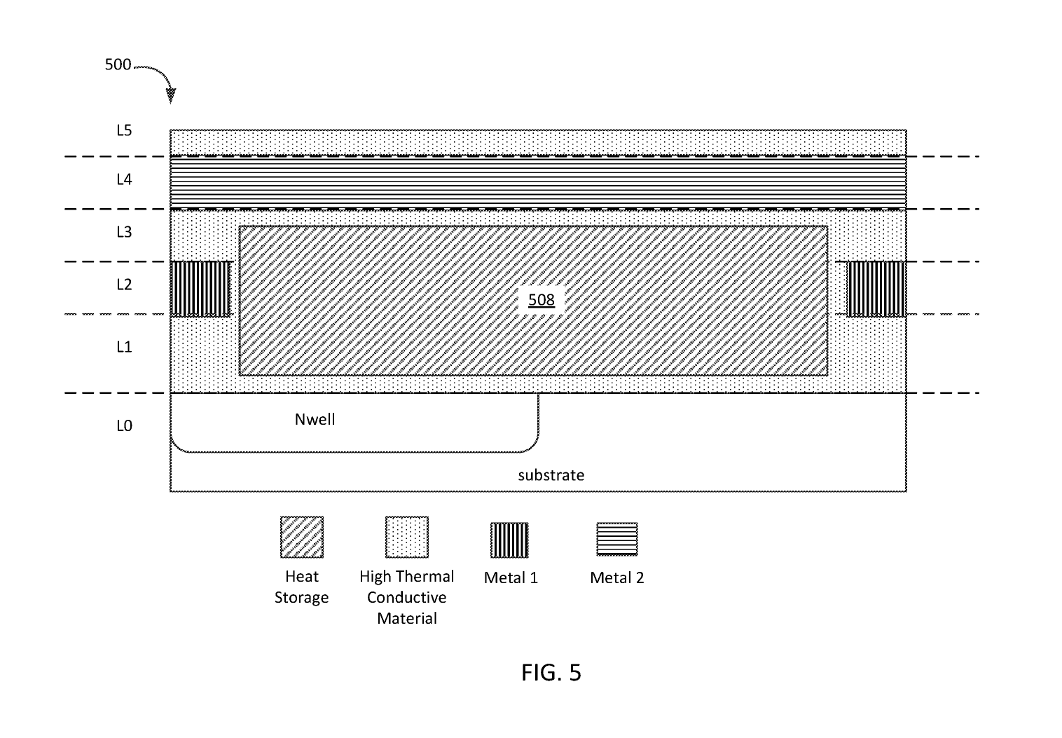

Alternatively, the heat generated by the neighboring standard cells may be stored in the thermal cell 228. FIG. 5 illustrates another exemplary cross-section of the FIG. 2 along line B-B′ with an alternative embodiment. The embodiment illustrated cross-section 500 is similar to the cross-section 400 but a portion of the thermal material is replaced with a heat storage material 508. The heat storage material 508 may absorb part of the heat from the neighboring standard cells without spreading out to the air. The heat storage material 508 may be surrounded by electrical isolated and thermal conductive materials.

Suitable heat storage materials include phase change materials (PCMs). PCMs are substances that absorb and release thermal energy during the process of melting and freezing (solid/liquid phase transition). When a PCM freezes, it releases a large amount of energy in the form of latent heat at a relatively constant temperature. Conversely, when such material melts, it absorbs a large amount of heat from the environment. A specialized group of PCMs undergo a solid/solid phase transition with the associated absorption and release of large amounts of heat. These materials change their crystalline structure from one lattice configuration to another at a fixed and well-defined temperature, and the transformation can involve latent heats comparable to the most effective solid/liquid PCMs. Such materials are useful because, unlike solid/liquid PCMs, there is no visible change in the appearance of the PCM (other than a slight expansion/contraction), and there are no problems associated with handling liquids, i.e. containment, potential leakage, etc. Solid/solid PCMs are ideal for use in a thermal cell to store the heat. Example of solid/solid PCMs may be composed of polyacrylonitrile, binary of fatty acids ((blending of stearic acid (SA) and lauric acid (LA)), and zeolite molecular sieve (ZMS).

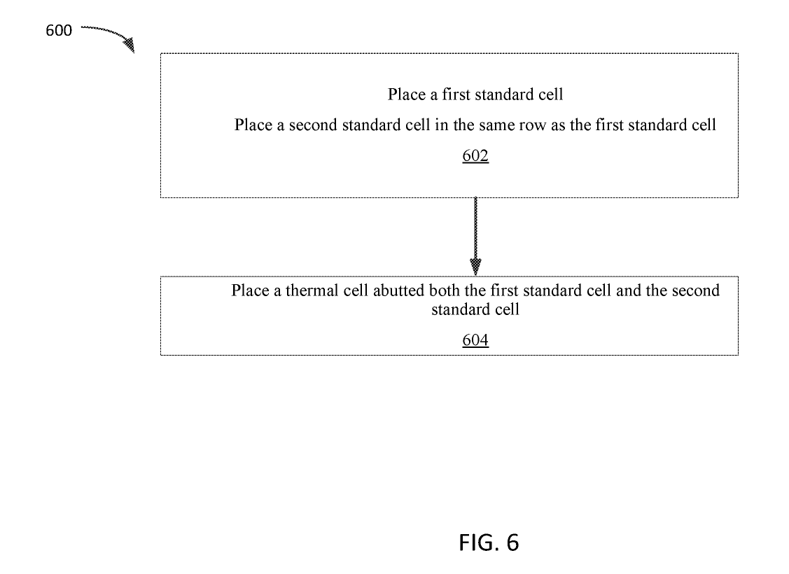

FIG. 6 illustrates an exemplary method of placing a thermal cell in a circuit design. Method 600 strategically places a thermal cell within a circuit row to mitigate the thermal issue caused by heat generated by other standard cells. At 602, a first standard cell (e.g., the standard cell 222, 224) is placed in the circuit row. The first standard cell has a height equal to a cell height. A second standard cell (e.g., the standard cell 226) having a height equal to the cell height is placed in the same circuit row as the first standard cell. The first standard cell and the second standard cell comprise a first dielectric material in the same layer (or layers).

At 604, a thermal cell (e.g., the thermal cell 228) having a height equal to the cell height is placed between the first standard cell and the second standard cell. The thermal cell is abutted to and aligned with both the first standard cell and the second standard cell. The thermal cell comprises a second dielectric material having a higher thermal conductivity than the first dielectric material in the same layer or layers (e.g., layer L1, L2, L3, or L4). The first dielectric material may be SiO₂ or other suitable materials. The second material may be AlN, BN, polycrystalline diamond, or their alloys, or other suitable materials, or their combination thereof.

The thermal cell may be placed wherever the neighboring standard cell or cells may generate a large amount of heat. The thermal materials may be placed layer by layer (or sub-layer by sub-layer) or multiple layers in one step (or multiple steps) The different layers (or sub-layers) may have different thermal materials. The thermal cell may further comprise an Nwell to maintain the Nwell continuity with the neighboring standard cells. The thermal cell may also comprise power and/or ground rails to maintain the power and/or ground rails continuity with the neighboring standard cells. In addition, there may be more than one thermal cell. There may be one thermal cell in the left side of a standard cell and another thermal cell in the right side of the standard cell. The plurality of thermal cells may be identical or may be different in structure and/or in size.

Alternatively, the thermal cell may comprise a heat storage material. A good heat storage material may be PCMs, particularly solid/solid PCMs. The heat storage material may be surrounded by other high thermal conductivity dielectric material.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. An integrated circuit, comprising:
A first standard cell having a height equal to a cell height, wherein the first standard cell comprises a first dielectric material in a first layer;
A second standard cell having a height equal to the cell height and aligning with the first standard cell, wherein the second standard cell comprises the first dielectric material in the first layer; and
A first thermal cell having a height equal to the cell height and aligning with and abutting to both the first standard cell and the second standard cell, wherein the first thermal cell comprises a second dielectric material in the first layer having a higher thermal conductivity than that of the first dielectric material.

2. The integrated circuit of claim 1, wherein the second dielectric material comprises one of AlN, BN, polycrystalline diamond, or their alloys.

3. The integrated circuit of claim 1, wherein the first standard cell further comprises a third dielectric material in a second layer; the second standard cell further comprises the third dielectric material in the second layer; and the first thermal cell further comprises a fourth dielectric material in the second layer having a higher thermal conductivity than that of the third dielectric material.

4. The integrated circuit of claim 3, wherein the third dielectric material is different to the first dielectric material; and wherein the fourth dielectric material is same as the second dielectric material.

5. The integrated circuit of claim 4, wherein both the second and the fourth materials comprise one of AlN, BN, polycrystalline diamond, or their alloys.

6. The integrated circuit of claim 1, wherein the first standard cell further comprises a third dielectric material in a second layer; the second standard cell further comprises the third dielectric material in the second layer; and the first layer and the second layer of the first thermal cell comprise the second dielectric material deposited in the same one or more steps.

7. The integrated circuit of claim 1, wherein an Nwell for the first standard cell, an Nwell for the second standard cell, and an Nwell for the first thermal cell are abutted and merged into one large nwell.

8. The integrated circuit of claim 1, wherein a power rail for the first standard cells, a power rail for the second standard cell, and a power rail for the first thermal cell are abutted to form a common power rail arranged along a straight line.

9. The integrated circuit of claim 1 further comprising a second thermal cell abutted to the first standard cell, wherein the second thermal cell has a height equal to the cell height aligning with the first standard cell, the second standard cell, and the first thermal cell.

10. The integrated circuit of claim 9, wherein the second thermal cell is same as the first thermal cell.

11. The integrated circuit of claim 1, wherein the first thermal cell further comprises a heat storage material.

12. The integrated circuit of claim 11, wherein the heat storage material is a solid/solid phase change material (PCM).

13. The integrated circuit of claim 11, wherein the heat storage material is surrounded by the second dielectric material.

14. A method, comprising:
Placing a first standard cell in a circuit row, wherein the first standard cell has height equal to a cell height and comprises a first dielectric material in a first layer;
Placing a second standard cell in the circuit row, wherein the second standard cell has a height equal to the cell height and comprises the first dielectric material in the first layer; and
Placing a first thermal cell in the circuit row abutted to both the first standard cell and the second standard cell, wherein the first thermal cell has a height equal to the cell height, wherein the first standard cell, the second standard cell, and the first thermal cell are aligned; and wherein the first thermal cell comprises a second dielectric material in the first layer having a higher thermal conductivity than that of the first dielectric material.

15. The method of claim 14, wherein the second dielectric material comprises one of AlN, BN, polycrystalline diamond, or their alloys.

16. The method of claim 14, wherein an Nwell for the first standard cell, an Nwell for the second standard cell, and an Nwell for the first thermal cell are abutted and merged into one large nwell.

17. The method of claim 14, wherein a power rail for the first standard cells, a power rail for the second standard cell, and a power rail for the first thermal cell are abutted to form a common power rail arranged along a straight line.

18. The method of claim 14 further comprising placing a second thermal cell abutted to the first standard cell, wherein the second thermal cell has a height equal to the cell height and is aligned with the first standard cell, the second standard cell, and the first thermal cell.

19. The method of claim 18, wherein the second thermal cell is same as the first thermal cell.

20. The method of claim 14, wherein the first thermal cell further comprises a heat storage material.

21. The method of claim 20, wherein the heat storage material is a solid/solid phase change material (PCM).

22. The method of claim 20, wherein the heat storage material is surrounded by the second dielectric material.
